(19) United States
(12) Patent Application Publication
(10) Pub. No.: US 2025/0006749 A1
(43) Pub. Date: Jan. 2, 2025

(54) IMAGE SENSING COMPUTING UNIT AND ITS OPERATING METHOD, IMAGE SENSING COMPUTER AND ELECTRONIC DEVICE

(71) Applicant: PEKING UNIVERSITY, Beijing (CN)

(72) Inventors: Zheng ZHOU, Beijing (CN); Guihai YU, Beijing (CN); Xiaoyan LIU, Beijing (CN); Jinfeng KANG, Beijing (CN); Peng HUANG, Beijing (CN)

(73) Assignee: PEKING UNIVERSITY, Beijing (CN)

(21) Appl. No.: 18/293,968

(22) PCT Filed: Aug. 17, 2022
(86) PCT No.: PCT/CN2022/113040

§ 371 Date: Jan. 31, 2024

(51) Int. Cl. H01L 27/146; H04N 25/77

(52) U.S. Cl. CPC H01L 27/14605; H01L 27/14612; H04N 25/77

(57) ABSTRACT

The present disclosure provides an image sensing computing unit and its operating method, an image sensing computer and an electronic device. Among them, the image sensing computing unit includes a first photosensitive unit and a second photosensitive unit. The second photosensitive unit is connected in series with the first photosensitive unit. The changing direction of the first threshold voltage of the first photosensitive unit when receiving light is opposite to the changing direction of the second threshold voltage of the second photosensitive unit when receiving light, so as to implement an in-situ logical operation between light input signals.

### CROSS-REFERENCE TO RELATED APPLICATION

This application is a Section 371 National Stage Application of International Application No. PCT/CN2022/113040, filed on Aug. 17, 2022, entitled “IMAGE SENSING COMPUTING UNIT AND ITS OPERATING METHOD, IMAGE SENSING COMPUTER AND ELECTRONIC DEVICE”, the content of which is hereby incorporated by reference in its entirety.

### TECHNICAL FIELD

The present disclosure relates to fields of semiconductor technology and integrated circuit technology, and in particular, to an image sensing computing unit and its operating method, an image sensing computer and an electronic device.

### BACKGROUND

An image sensing computing system may effectively realize the image perception processing functions such as the face recognition and the fingerprint recognition, and is widely used in fields of monitoring security and human-computer interaction. The traditional image sensing computing system includes an image sensing module and a computing processing module. It is required to convert light signal into an electrical signal in the image sensing module first, and then transmit it to the computing processing module for logical operations, so that the image sensing computing system is complex, the amount of redundant data is large, and the passing distance is long, thereby seriously affecting the image perception computing efficiency of the system.

### SUMMARY

An aspect of the present disclosure provides an image sensing computing unit, including a first photosensitive unit and a second photosensitive unit. The second photosensitive unit is connected in series with the first photosensitive unit. A changing direction of a first threshold voltage of the first photosensitive unit when receiving light is opposite to a changing direction of a second threshold voltage of the second photosensitive unit when receiving light, so as to realize an in-situ logical operation between light input signals.

According to embodiments of the present disclosure, the first photosensitive unit includes a first transistor, a first buried oxide layer and a first doped well layer. The first buried oxide layer is located below the first transistor. The first doped well layer is located below the first buried oxide layer.

According to embodiments of the present disclosure, the second photosensitive unit includes a second transistor, a second buried oxide layer and a second doped well layer. The second buried oxide layer is located below the second transistor. The second doped well layer is located below the second buried oxide layer.

According to embodiments of the present disclosure, a transistor type of the first transistor is different from a transistor type of the second transistor. A well doped type of the first doped well layer is the same as a well doped type of the second doped well layer. According to embodiments of the present disclosure, a source electrode of the first transistor is connected to a power supply voltage, a drain electrode of the first transistor is connected to a drain electrode of the second transistor, and a source electrode of the second transistor is grounded. A gate electrode of the first transistor is connected to a first gate control voltage. A gate electrode of the second transistor is connected to a second gate control voltage. The first doped well layer is connected to a first well control voltage, and the second doped well layer is connected to a second well control voltage.

Another aspect of the present disclosure provides a method for operating the above-mentioned image sensing computing unit, including: performing an exposure operation on the image sensing computing unit in an off state, so that an equivalent resistance of a first photosensitive unit and/or a second photosensitive unit in the image sensing computing unit changes; controlling a first gate control voltage of the first photosensitive unit and/or a second gate control voltage of the second photosensitive unit after the exposure operation, which is to generate an output voltage of the image sensing computing unit and achieve a readout operation for the image sensing computing unit; and controlling the first gate control voltage of the first photosensitive unit and/or the second gate control voltage of the second photosensitive unit has undergone the readout operation, which is to turn off the first photosensitive unit and/or the second photosensitive unit, and simultaneously controlling a first well control voltage and/or a second well control voltage to implement a reset operation for the image sensing computing unit.

According to embodiments of the present disclosure, the performing an exposure operation on the image sensing computing unit in an off state includes: controlling the first gate control voltage of the first photosensitive unit in the image sensing computing unit and/or the second gate control voltage of the second photosensitive unit in the image sensing computing unit, so that the first photosensitive unit and/or the second photosensitive unit in the image sensing computing unit are turned off, which makes that the image sensing computing unit is in the off state; and controlling a first well control voltage of the first photosensitive unit and/or a second well control voltage of the second photosensitive unit to implement the exposure operation.

According to embodiments of the present disclosure, the controlling a first gate control voltage of the first photosensitive unit and/or a second gate control voltage of the second photosensitive unit of the image sensing computing unit after the exposure operation to generate an output voltage of the image sensing computing unit including: controlling, when the first well control voltage of the first photosensitive unit and/or the second well control voltage of the second photosensitive unit remain unchanged, the first gate control voltage and/or the second gate control voltage to turn on the first photosensitive unit and/or the second photosensitive unit; and reading a drain terminal voltage between the first photosensitive unit and the second photosensitive unit as the output voltage.

Another aspect of the present disclosure provides an image sensing computer, including an image sensing array including the above-mentioned image sensing computing unit.

Yet another aspect of the present disclosure provides an electronic device, including the above-mentioned image sensing computing unit.

### BRIEF DESCRIPTION OF THE DRAWINGS

FIG. 1 schematically shows a circuit schematic diagram of an image sensing computing unit according to an embodiment of the present disclosure;

FIG. 2 schematically shows a structural diagram of an N-p type photosensitive unit and a corresponding equivalent circuit diagram thereof, and a diagram of a changing relationship of threshold voltage Vₜₕ with light intensity according to an embodiment of the present disclosure:

FIG. 3 schematically shows a structural diagram of an N-n type photosensitive unit and a corresponding equivalent circuit diagram thereof, and a diagram of a changing relationship of threshold voltage Vₜₕ with light intensity according to an embodiment of the present disclosure:

FIG. 4 schematically shows a structural diagram of a P-p type photosensitive unit and a corresponding equivalent circuit diagram thereof, and a diagram of a changing relationship of threshold voltage Vₜₕ with light intensity according to an embodiment of the present disclosure:

FIG. 5 schematically shows a structural diagram of a P-n type photosensitive unit and a corresponding equivalent circuit diagram thereof, and a diagram of a changing relationship of threshold voltage Vₜₕ with light intensity according to an embodiment of the present disclosure:

FIG. 6 schematically shows an equivalent circuit diagram of an image sensing computing unit including a P-n type photosensitive unit and an N-n type photosensitive unit that may implement ‘NOR’/‘NAND’ logic between light signals, and a corresponding ‘NOR’/‘NAND’ operation output schematic diagram according to an embodiment of the present disclosure:

FIG. 7 schematically shows an equivalent circuit diagram of an image sensing computing unit including a P-p type photosensitive unit and an N-p type photosensitive unit that may implement ‘AND’/‘OR’ logic between light signals, and a corresponding ‘AND’/‘OR’ operation output diagram according to an embodiment of the present disclosure:

FIG. 8 schematically shows a flowchart of a method for operating an image sensing computing unit according to an embodiment of the present disclosure; and

FIG. 9 schematically shows an operation timing diagram of the above-mentioned image sensing computing unit that may implement a logical operation between light inputs according to an embodiment of the present disclosure.

### DETAILED DESCRIPTION OF EMBODIMENTS

In order to make purposes, technical solutions and advantages of the present invention more clear, the present invention will be further described in detail below with reference to specific embodiments and the accompanying drawings.

It should be noted that implementation methods not shown or described in the drawings or the text of the specification are all forms known to those of ordinary skill in the technical field and have not been described in detail. In addition, definitions of each element and method are not limited to the various specific structures, shapes or methods mentioned above in embodiments, which may be simply modified or replaced by those of ordinary skill in the art.

It should also be noted that the directional terms mentioned in the embodiments, such as “up”, “down”, “front”, “back”, “left”, “right”, etc., are only for reference to the directions of the drawings, not used to limit the scope of the present disclosure. Throughout the drawings, the same elements are designated by the same or similar reference numerals. Conventional structures or constructions will be omitted where they may obscure the understanding of the present disclosure.

Moreover, the shapes and sizes of the components in the figures do not reflect the actual sizes and proportions, but only illustrate the contents of embodiments of the present disclosure. Furthermore, in the claims, any reference signs between parentheses shall not be construed as limiting the claim.

Furthermore, the word “comprising” does not exclude the presence of elements or steps not listed in a claim. The word “a” or “an” preceding an element does not exclude the presence of a plurality of such elements.

The serial numbers used in the description and claims, such as “first”, “second”, “third”, etc., are used to modify the corresponding elements. They themselves do not mean that the element has any ordinal number, nor do they represent an order of a certain component with another component or an order of a manufacturing method. The use of these serial numbers is only used to clearly distinguish one component with a certain name from another component with the same name.

Those skilled in the art will understand that modules in the devices in an embodiment may be adaptively changed and provided in one or more devices different from that in the embodiment. The modules or units or components in the embodiments may be combined into one module or unit or component, and furthermore they may be divided into a plurality of sub-modules or sub-units or sub-components. Except that at least some of such features and/or processes or units are mutually exclusive, all features disclosed in this specification (including the accompanying claims, abstract and drawings) and any method so disclosed or all processes or units of the device may be employed in any combination. Unless expressly stated otherwise, each feature disclosed in this specification (including accompanying claims, abstract and drawings) may be replaced by alternative features serving the same, equivalent or similar purpose. Furthermore, in the element claim enumerating several means, several of these means may be embodied by the same item of hardware.

Similarly, it should be understood that in the above description of exemplary embodiments of the present disclosure, in order to simplify the present disclosure and assist in understanding one or more of various aspects of the present disclosure, various features of the present disclosure are sometimes grouped together into a single embodiment, figure, or in its description. However, this method of the present disclosure is not to be interpreted as reflecting an intention that the present disclosure requires more features than are expressly recited in each claim. Rather, as reflected by the following claims, disclosed aspects lie in less than all features of a single foregoing disclosed embodiment. Thus, the claims following the detailed description of embodiments are hereby expressly incorporated into this detailed description of embodiments, with each claim being implemented as a separate embodiment of the present disclosure.

In order to solve the technical problems in the related art that a more complex system composition and low logical processing efficiency which are caused by the traditional image sensing computing system that requires a signal computing processing module to implement light signal computing processing, the present disclosure provides an image sensing computing unit that may directly implement logical operation between light signals and its operating method, an image sensing computer and an electronic device.

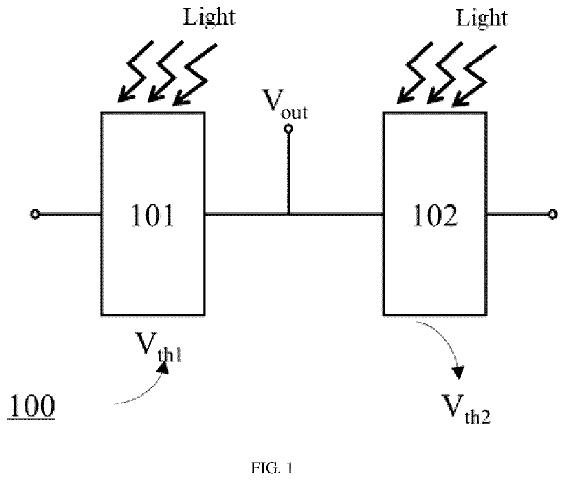

As shown in FIG. 1, an aspect of the present disclosure provides an image sensing computing unit 100, where the image sensing computing unit 100 includes a first photosensitive unit 101 and a second photosensitive unit 102. The second photosensitive unit 102 is connected in series with the first photosensitive unit 101.

Among them, a changing direction of a first threshold voltage Vₜₕ₁ of the first photosensitive unit 101 when receiving light is opposite to a changing direction of a second threshold voltage Vₜₕ₂ of the second photosensitive unit 102 when receiving light, so as to implement an in-situ logical operation between light input signals.

The image sensing computing unit 100 may be a structural unit with a photoelectric conversion function, where both the first photosensitive unit 101 and the second photosensitive unit 102 may be transistor units with photosensitive function.

The first photosensitive unit 101 and the second photosensitive unit 102 are connected in series with each other, and their respective equivalent resistances in the connected circuit directly affect a voltage division effect of the two in the circuit. A photosensitive unit with a larger equivalent resistance has a larger voltage value of the voltage division. A photosensitive unit with a relatively smaller equivalent resistance has a relatively smaller voltage value of the voltage division. At this time, if these two photosensitive units connected in series may show threshold voltages in different changing directions under their respective light conditions, their corresponding equivalent resistances also have corresponding different changing directions. For example, when the first photosensitive unit 101 is illuminated, the first threshold voltage Vₜₕ₁ is increased and the equivalent resistance is increased. Correspondingly, when the second photosensitive unit 102 is illuminated, the second threshold voltage Vₜₕ₂ is decreased and the equivalent resistance is decreased. In this way, different lighting conditions correspond to different voltage division conditions of the two photosensitive units. An output voltage Vₒᵤₜ output at an output terminal of the image sensing computing unit 100 may be directly served as a voltage signal output of a corresponding logical operation result without the requirements for additional processing by other operation processing modules, so as to implement in-situ logical operation between light input signals.

The threshold voltages of the two photosensitive units in the above-mentioned embodiments of the present disclosure change in opposite directions when illuminated, so that their corresponding equivalent resistances change in opposite directions when illuminated. When the two are connected in series, the voltage division relationship between the two will also be different depending on the light conditions of the two. By setting a reasonable voltage comparison value to determine the logical value corresponding to the output voltage value, the in-situ logical operation between light input signals may be implemented.

Therefore, compared to the situation that the image sensing module in the related art may only be used for photoelectric signal conversion, and the output electrical signal still requires to be further conversion processed by the signal operation processing module in order to ultimately implement the logical operation between light input signals, the image sensing computing unit of embodiments of the present disclosure may directly perform photoelectric conversion while implementing in-situ logical processing function, so that the image sensing computing unit directly outputs an electrical signal representing a corresponding logical operation result, thereby eliminating the signal processing module for traditional logical processing, effectively reducing the complexity of the system and improving the efficiency of light signal processing.

It should be noted that the image sensing computing unit in the present disclosure may implement in-situ logical operation between light signals, and the input of light signal may discussed with light as a logical value “1” and light-free as a logical value “0”. Therefore, those skilled in the art should understand that if light is set as the logical value “0” and light-free is set as the logical value “1”, the image sensing computing unit of embodiments of the present disclosure implements the reverse logical operation to the above discussion that “light is set as the logical value ‘1’ and light-free is set as the logical value ‘0’”, which will not be further repeated in the following text.

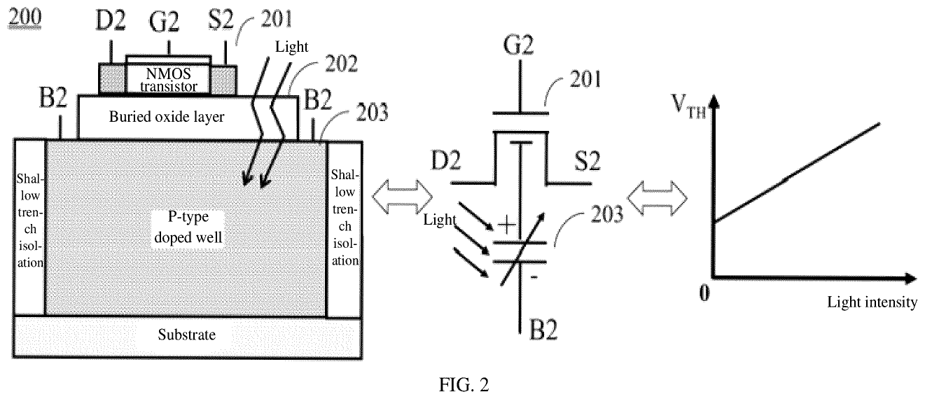

As shown in FIG. 2 to FIG. 7, according to embodiments of the present disclosure, the first photosensitive unit includes a first transistor, a first buried oxide layer and a first doped well layer.

The first buried oxide layer is located below the first transistor.

The first doped well layer is located below the first buried oxide layer.

As shown in FIG. 2 to FIG. 7, according to embodiments of the present disclosure, the second photosensitive unit includes a second transistor, a second buried oxide layer and a second doped well layer.

The second buried oxide layer is located below the second transistor.

The second doped well layer is located below the second buried oxide layer.

As shown in FIG. 2 to FIG. 7, the photosensitive unit of the embodiments of the present disclosure may be a semiconductor structure with transistors and doped well layers respectively disposed above and below the buried oxide layer. The semiconductor structure may form an ultra-thin body and buried oxide structural photosensitive transistor unit, that is, a UTBB photosensitive transistor unit. The semiconductor structure also includes a substrate layer with supporting function disposed below the doped well layer, and an isolation groove with an isolation function located on two sides of the doped well layer. The isolation groove is generally used as shallow groove isolation, so that the corresponding photosensitive unit is isolated from other adjacent device units. A buried oxide layer is formed on a surface of the doped well layer, and a transistor is formed on a surface of the buried oxide layer, so as to form a main structure of the photosensitive unit.

Among them, for the same image sensing computing unit, the structural form of a first photosensitive unit is the same as the structural form of a second photosensitive unit, where the first photosensitive unit is connected in series with the second photosensitive unit, and there may be differences in the specific structural materials and structural functional types of specific structural layers. Thus, it may be ensured that the two may present threshold voltages in different changing directions when exposed to light. Thereby, it is possible to ensure the in-situ logical processing effect between the light signals of the image sensing computing unit of embodiments of the present disclosure.

As shown in FIG. 2 to FIG. 7, according to embodiments of the present disclosure, a transistor type of the first transistor is different from a transistor type of the second transistor, and a well doped type of the first doped well layer is the same as a well doped type of the second doped well layer.

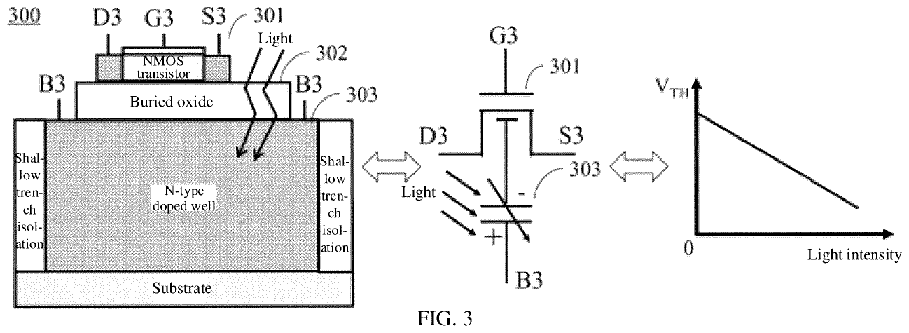

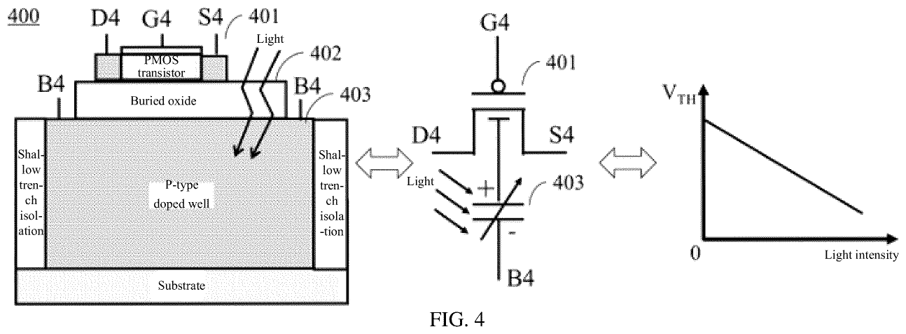

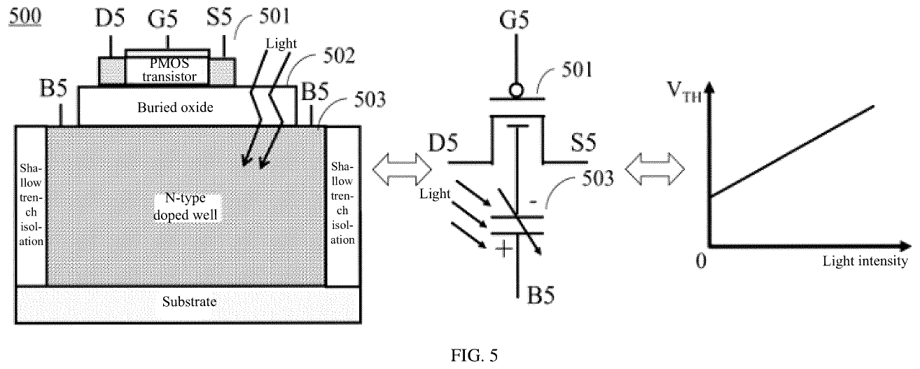

The transistor type may be an N-type doped or P-type doped field-effect transistor, such as NMOS and PMOS. The well doped type may be N-type doped and P-type doped well structures. As shown in FIG. 2 to FIG. 5, according to the different transistor types and well doped types, the above-mentioned photosensitive units of embodiments of the present disclosure may be divided into N-p photosensitive unit 200 of NMOS transistor 201+P-type doped well layer 203 (as shown in FIG. 2), N-n photosensitive unit 300 of NMOS transistor 301+N-type doped well layer 303 (as shown in FIG. 3), P-p photosensitive unit 400 of PMOS transistor 401+P-type doped well layer 403 (as shown in FIG. 4) and P-n photosensitive unit 500 of PMOS transistor 501+N-type doped well layer 503 (as shown in FIG. 5). A structural layer of a buried oxide layer is separated between each transistor and the corresponding doped well layer, such as buried oxide layers 202, 302, 402 and 502. The buried oxide layer may be a supporting layer with high transparency, such as a silicon dioxide layer, which may allow light to irradiate through and illuminate the doped well layers. Therefore, when a transistor is provided, it is required to reserve a light window for light on the surface of the buried oxide layer, so that the transistor may not fully cover the buried oxide layer.

Among them, each transistor may have a gate terminal G, a drain terminal D and a source terminal S. Corresponding doped well layer has a lead terminal B. Specifically, as shown in FIG. 2, the gate terminal G2, drain terminal D2, source terminal S2 and lead terminal B2 of the N-p photosensitive unit are shown. As shown in FIG. 3, the gate terminal G3, drain terminal D3, source terminal S3 and lead terminal B3 of the N-n photosensitive unit are shown. As shown in FIG. 4, the gate terminal G4, drain terminal D4, source terminal S4 and lead terminal B4 of the P-p photosensitive unit are shown. As shown in FIG. 5, the gate terminal G5, drain terminal D5, source terminal S5 and lead terminal B5 of the P-n photosensitive unit are shown. It can be seen that, as shown in corresponding equivalent circuits, each photosensitive unit is a circuit form in which a back gate of a transistor unit is cascaded to a photosensitive capacitor. The capacitance value of the corresponding photosensitive capacitor may be reduced as the effect of illumination increases, or may be increased as the effect of illumination increases. Preferably, the capacitance value of the photosensitive capacitor corresponding to each photosensitive unit may be reduced as the effect of illumination increases. Thereby, it is possible to ensure that after the corresponding photosensitive units are connected in series with each other, the threshold voltages of the corresponding photosensitive units change in opposite directions after being illuminated, so as to implement the in-situ light logical operation mentioned above of the image sensing computing unit.

Combined with the structural composition diagram of the photosensitive unit shown in FIG. 2 to FIG. 5, the corresponding equivalent circuit diagram and the schematic diagram of the changing of the threshold voltage V_{TH} of the photosensitive unit with illumination, the working principle of each photosensitive unit mentioned above when illuminated is further explained as follows.

As shown in FIG. 2, when the doped well layer 203 of the N-p photosensitive unit 200 is exposed, a well control voltage V_{B}<0 corresponding to the lead terminal B2 may be controlled. A depletion region is generated in the well corresponding to the doped well layer 203 and photo-generated electrons are collected, thereby lowering the potential of the depletion region. On the one hand, its equivalent capacitance is reduced, and on the other hand, it produces a back gate modulation effect on the NMOS transistor 201 above the buried oxide layer 202, so as to cause the threshold voltage V_{TH} of the NMOS transistor 201 to be increased.

As shown in FIG. 4, when the doped well layer 403 of the P-p photosensitive unit 400 is exposed, the well control voltage V_{B}<0 corresponding to the lead terminal B4 may be controlled. A depletion region is generated in the well corresponding to the doped well layer 403 and photo-generated electrons are collected, thereby lowering the potential of the depletion region. On the one hand, its equivalent capacitance is reduced, and on the other hand, it produces a back gate modulation effect on the PMOS transistor above the buried oxide layer 402, so as to cause the threshold voltage V_{TH} of the PMOS transistor 401 to be reduced.

As shown in FIG. 3, when the N-n photosensitive unit 300 is exposed, the well control voltage V_{B}>0 corresponding to the doped well layer 303 may be controlled. The depletion region of the doped well layer 303 collects photo-generated holes, thereby raising the potential of the depletion region and reducing its equivalent capacitance. At the same time, a back gate modulation effect on the NMOS transistor 301 is opposite to that of the photosensitive unit of the P-type doped well layer mentioned above, so that the threshold voltage V_{TH} of the NMOS transistor 301 is reduced.

As shown in FIG. 5, when the P-n photosensitive unit 500 is exposed, the well control voltage V_{B}>0 corresponding to the doped well layer 503 may be controlled. The depletion region of the doped well layer 503 collects photo-generated holes, thereby raising the potential of the depletion region and reducing its equivalent capacitance. At the same time, a back gate modulation effect on the PMOS transistor 501 is opposite to that of the photosensitive unit of the P-type doped well layer mentioned above, so that the threshold voltage V_{TH} of the PMOS transistor 501 is increased.

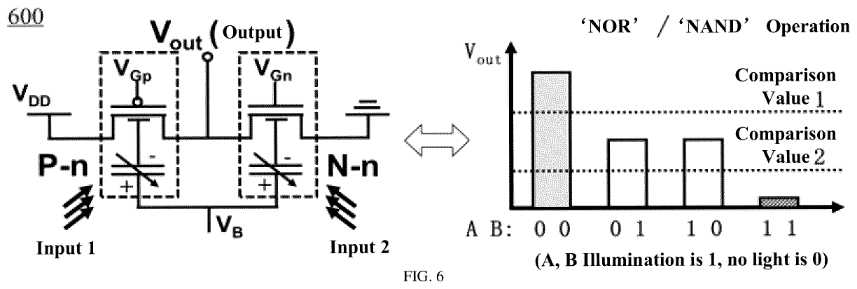

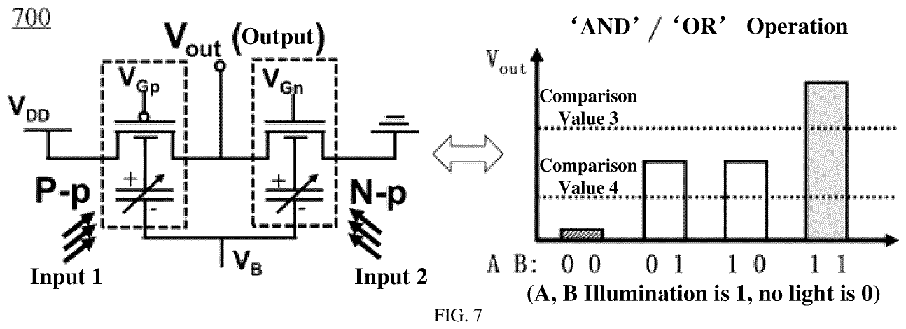

Based on the corresponding relationship between the illumination of the photosensitive units of each transistor type mentioned above and the threshold voltage V_{TH}, combined with the equivalent circuit diagrams of the image sensing computing units of two different photosensitive units and corresponding output results shown in FIG. 6 and FIG. 7, the image sensing computing unit 600 that may implement ‘NOR’/‘NAND’ logic between light signals in embodiments of the present disclosure and the image sensing computing unit 700 that may implement ‘OR’/‘AND’ logic between light signals are explained as follows.

As shown in FIG. 6, the image sensing computing unit 600 implements ‘NOR’/‘NAND’ logic between light signals by the P-n photosensitive unit being connected in series with the N-n photosensitive unit. After the P-n photosensitive unit is exposed, the threshold voltage V_{TH} is increased, and its equivalent resistance is increased. After exposure of the N-n photosensitive unit connected in series with the P-n photosensitive unit mentioned above, the threshold voltage V_{TH} is reduced and its equivalent resistance is reduced.

The P-n photosensitive unit and the N-n photosensitive unit are connected in series to implement voltage division. The proportion of the equivalent resistance of the PMOS transistor is larger, and the value of the output result Vₒᵤₜ is smaller. It is possible to set the input light of the photosensitive unit as the logical value ‘1’, and light-free as the logical value ‘0’.

Therefore, when the two photosensitive units connected in series are both illuminated, that is, when the light input is ‘1 1’, the output value of the output voltage Vₒᵤₜ is the minimum. When only one of the two photosensitive units connected in series mentioned above is illuminated, that is, when the light input is ‘1 0’ and ‘0 1’, the output value of the output voltage Vₒᵤₜ takes second place. When the two photosensitive units connected in series mentioned above are not illuminated, that is, when the light input is ‘0 0’, the output value of the output voltage Vₒᵤₜ is the maximum.

It can be seen that the logical value represented by the output voltage Vₒᵤₜ of the corresponding image sensing computing unit may be further determined by setting two different voltage comparison values (comparison values 1 and 2 as shown in FIG. 6). If the logical value is greater than the comparison value, ‘1’ is output. If the logical value is less than the comparison value, ‘0’ is output. Two different comparison values may obtain two logical results ‘NOR’ or ‘NAND’. Among them, a larger comparison value 1 is set to ensure that only when the output voltage Vₒᵤₜ is ‘1’ with input of ‘1 1’, the ‘NAND’ operation is implemented. On the contrary, a smaller comparison value 2 is set, the ‘NOR’ operation is implemented, which will not be repeated here.

As shown in FIG. 7, the image sensing computing unit 700 implements ‘OR’/‘AND’ logic between light signals by the P-p photosensitive unit being connected in series with the N-p photosensitive unit. After the P-p photosensitive unit is exposed, the threshold voltage V_{TH} is reduced, and its equivalent resistance is reduced. After exposure of the N-p photosensitive unit connected in series with the P-p photosensitive unit mentioned above, the threshold voltage V_{TH} is increased and its equivalent resistance is increased.

Therefore, the working principle of the image sensing computing unit 600 is similar to that shown in FIG. 6 above, but the functional performance is basically the opposite. When the two photosensitive units connected in series are both illuminated, that is, when the light input is ‘1 1’, the output value of the output voltage Vₒᵤₜ is the maximum. When only one of the two photosensitive units connected in series mentioned above is illuminated, that is, when the light input is ‘1 0’ and ‘0 1’, the output value of the output voltage Vₒᵤₜ takes second place. When the two photosensitive units connected in series mentioned above are not illuminated, that is, when the logical value of the light input is ‘0 0’, the output value of the output voltage Vₒᵤₜ is the minimum.

It can be seen that by setting two different voltage comparison values (comparison values 3 and 4 as shown in FIG. 7), two logical results of ‘OR’ or ‘AND’ may be obtained. A larger comparison value 3 is set to ensure that only when the output voltage Vₒᵤₜ is ‘l’ with input of ‘1 1’, the ‘AND’ operation is implemented. A smaller comparison value 4 is set, the ‘OR’ operation is implemented, which will not be repeated here.

Therefore, the above-mentioned image sensing computing unit of embodiments of the present disclosure may include two photosensitive transistor units (UTBB photosensitive transistor units) of ultra-thin bodies with different transistor types and the same well doped type and buried oxide structures, where two photosensitive transistor units are connected in series with each other. Since the two photosensitive units with different transistor types and the same well doped type, the changing direction of the threshold voltage of one of two photosensitive units is opposite to the changing direction of the threshold voltage of the other one of the two photosensitive units when illuminated, so that the changing trends of their equivalent resistances when illuminated are opposite to each other. When the two are connected in series, the voltage division relationship between the two will be different depending on the different illuminating conditions. Therefore, the logical value corresponding to the output voltage value may be determined by setting the voltage comparison value, so as to implement in-situ logical operation between light input signals.

As shown in FIG. 2 to FIG. 7, according to embodiments of the present disclosure, a source electrode of the first transistor is connected to a power supply voltage.

A drain electrode of the first transistor is connected to a drain electrode of the second transistor.

A source electrode of the second transistor is grounded.

A gate electrode of the first transistor is connected to a first gate control voltage, a gate electrode of the second transistor is connected to a second gate control voltage, the first doped well layer is connected to a first well control voltage, and the second doped well layer is connected to a second well control voltage.

As shown in FIG. 6, the image sensing computing unit 600 that may implement logical operations of ‘NOR’ or ‘NAND’ between input light signals may include the P-n photosensitive unit and the N-n photosensitive unit which are connected in series. Among them, the source electrode of the P-n photosensitive unit is connected to the power supply voltage V_{DD}, the drain electrode of the P-n photosensitive unit is connected to the drain electrode of the N-n photosensitive unit, and the source electrode of the N-n photosensitive unit is grounded. In addition, the gate electrode of the P-n photosensitive unit may be connected to the gate control signal V_{Gp}, the gate electrode of the N-n photosensitive unit may be connected to another gate control signal V_{Gn.}, and the respective well electrodes of the doped well layers of both are connected to the well control signal V_{B} together. Therefore, when the input of the image sensing computing unit 600 is an incident light of each photosensitive unit, the output is a drain terminal voltage corresponding to the N-n photosensitive unit.

As shown in FIG. 7, the image sensing computing unit 700 that may implement logical operation of ‘OR’ or ‘AND’ between input light signals may include the P-p photosensitive unit and the N-p photosensitive unit which are connected in series, that is, the source electrode of the P-p photosensitive unit is connected to V_{DD}, the drain electrode of the P-p photosensitive unit is connected to the drain electrode of the N-p photosensitive unit, and the source electrode of the N-p photosensitive unit is grounded. In addition, the gate electrode of the P-p photosensitive unit may be connected to the gate control signal V_{Gp}, the gate electrode of the N-p unit may be connected to another gate control signal V_{Gn}, and the respective well electrodes of the doped well layers of both may be connected to the well control signal V_{B} together. Therefore, when the input of the image sensing computing unit 700 is an incident light of each photosensitive unit, the output is a drain terminal voltage corresponding to the N-p photosensitive unit.

On this basis, the logical value of the output voltage Vₒᵤₜ may be further determined by setting a voltage comparison value, so as to implement logical operations such as ‘NOR’/‘NAND’ between light signals and ‘OR’/‘AND’ between light signals, without the requirements of additional circuit components such as signal operation processing modules, thereby simplifying the processing system, shortening the time of logical operation, and improving the efficiency of logical operation.

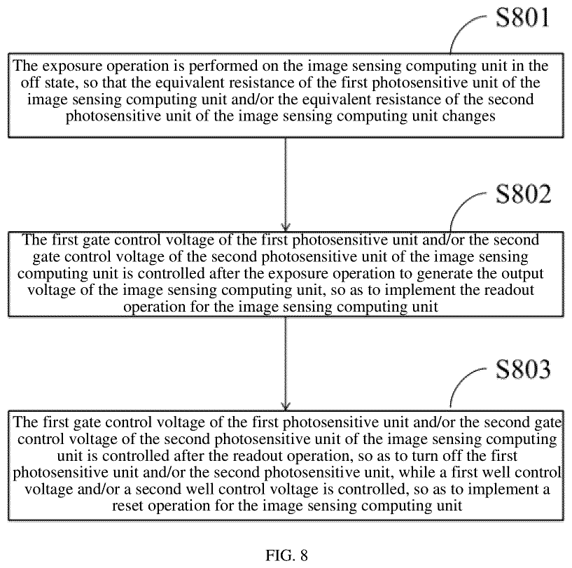

As shown in FIG. 8, another aspect of the present disclosure provides a method for operating the image sensing computing unit as shown in FIG. 1 to FIG. 7, which includes operations S801 to S803.

In operation S801, an exposure operation is performed on the image sensing computing unit in an off state, so that an equivalent resistance of a first photosensitive unit of the image sensing computing unit and/or an equivalent resistance of a second photosensitive unit of the image sensing computing unit change.

In operation S802, a first gate control voltage of the first photosensitive unit and/or a second gate control voltage of the second photosensitive unit of the image sensing computing unit is controlled after the exposure operation to generate an output voltage of the image sensing computing unit, so as to implement a readout operation for the image sensing computing unit.

In operation S803, the first gate control voltage of the first photosensitive unit and/or the second gate control voltage of the second photosensitive unit of the image sensing computing unit is controlled after the readout operation, so as to turn off the first photosensitive unit and/or the second photosensitive unit, while a first well control voltage and/or a second well control voltage is controlled, so as to implement a reset operation for the image sensing computing unit.

As shown in FIG. 6 to FIG. 9, according to embodiments of the present disclosure, in operation S801, an exposure operation is performed on the image sensing computing unit in an off state, including:
controlling the first gate control voltage of the first photosensitive unit of the image sensing computing unit and/or the second gate control voltage of the second photosensitive unit of the image sensing computing unit, so that the first photosensitive unit of the image sensing computing unit and/or the second photosensitive unit of the image sensing computing unit are turned off, and the image sensing computing unit is in the off state; and
controlling a first well control voltage of the first photosensitive unit and/or a second well control voltage of the second photosensitive unit to implement the exposure operation.

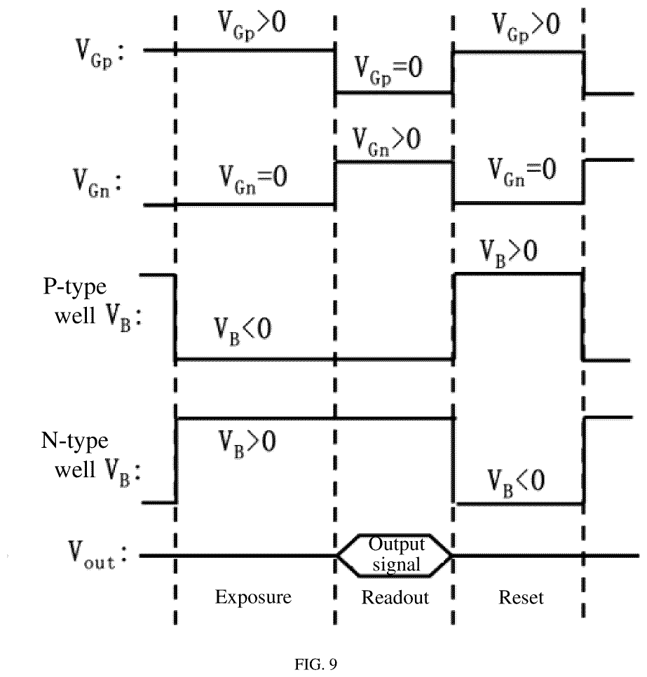

With reference to FIG. 6 or FIG. 7, as shown in FIG. 9, when the image sensing computing unit of embodiments of present disclosure performs an exposure operation, the gate control voltage V_{Gp}>0 and V_{Gn}=0 of the two photosensitive units which are connected in series are controlled to turn off and maintain this off state. In such off state, for the image sensing computing unit 600 including the P-n photosensitive unit and the N-n photosensitive unit as shown in FIG. 6, the well control voltage V_{B}<0 corresponding to the two doped well layers is controlled, and the exposure operation is performed on at least one of the two photosensitive units on this basis. Alternatively, in such off state, for the image sensing computing unit 700 including the P-p photosensitive unit and the N-p photosensitive unit as shown in FIG. 7, the corresponding well control voltage V_{B}>0 is controlled, and the exposure operation is performed on at least one of the two photosensitive units on this basis. In this way, the exposure operation of at least one of the two photosensitive units connected in series may be implemented.

As shown in FIG. 6 to FIG. 9, according to embodiments of the present disclosure, in operation S802, a first gate control voltage of the first photosensitive unit and/or a second gate control voltage of the second photosensitive unit of the image sensing computing unit is controlled after the exposure operation to generate an output voltage of the image sensing computing unit, including:
controlling, when the first well control voltage of the first photosensitive unit and/or the second well control voltage of the second photosensitive unit remain unchanged, the first gate control voltage and/or the second gate control voltage to turn on the first photosensitive unit and/or the second photosensitive unit; and
reading a drain terminal voltage between the first photosensitive unit and the second photosensitive unit as the output voltage.

With reference to FIG. 6 or FIG. 7, as shown in FIG. 9, when the corresponding image sensing computing unit performs a readout operation, the corresponding well control voltage V_{B} remains the same as the value when the exposure operation is performed, and the gate control voltage V_{Gp}=0 and V_{Gn}>0 corresponding to two different photosensitive units, so as to turn on such two photosensitive units, and directly reading out the value of the output signal Vₒᵤₜ.

As shown in FIG. 6 to FIG. 9, according to embodiments of the present disclosure, in operation S803, the first gate control voltage of the first photosensitive unit and/or the second gate control voltage of the second photosensitive unit of the image sensing computing unit is controlled after the readout operation, so as to implement a reset operation for the image sensing computing unit including:
controlling the first gate control voltage and/or the second gate control voltage, so as to turn off the first photosensitive unit and/or the second photosensitive unit; and
controlling a first well control voltage and/or a second well control voltage, so as to implement a reset operation.

With reference to FIG. 6 or FIG. 7, as shown in FIG. 9, when the corresponding image sensing computing unit performs a reset operation, the gate control voltage V_{Gp}>0 and V_{Gn}=0 corresponding to two different photosensitive units, the two photosensitive units are turned off again. In such on state, for the image sensing computing unit 600 including the P-n photosensitive unit and the N-n photosensitive unit as shown in FIG. 6, the well control voltages V_{B}>0 corresponding to the two doped well layers are controlled, so as to implement a reset of each photosensitive unit. Alternatively, in such on state, for the image sensing computing unit 700 including the P-p photosensitive unit and the N-p photosensitive unit as shown in FIG. 7, the well control voltages V_{B}<0 corresponding to the two doped well layers are controlled, so as to implement a reset of each photosensitive unit. In the process of implementing the reset operation, it is required to control the first well control voltage and/or the second well control voltage to be reversed to a voltage value that is opposite to a polarity of the corresponding well control voltage when the exposure operation is performed, so that the reset may be guaranteed.

Another aspect of the present disclosure provides an image sensing computer, including an image sensing array including the image sensing computing unit mentioned above. The image sensing array may have N×M image sensing computing units mentioned above, i.e. with 2N×M photosensitive units mentioned above, where two photosensitive units in each image sensing computing unit are connected in series with each other and maintain opposite changing direction in their respective threshold voltage when illuminated, so as to implement an in-situ logical operation between corresponding light signals, and allow the image sensing array to be directly served as an output device for logical voltage without the requirements of additional operation processing modules.

Yet another aspect of the present disclosure provides an electronic device, including the image sensing computer described above. This electronic device may be a device with at least one of functions of light communication and light imaging, such as light communication laser devices, so as to achieve image perception processing functions such as facial recognition and fingerprint recognition. It may also be a portable electronic device such as a laptop, a computer, an iPad, a smartphone, etc., which may be well applied in fields of monitoring security, human-machine interaction, etc., which will not be specifically restricted.

At this point, embodiments of the present disclosure have been provided in detail in conjunction with the accompanying drawings.

The specific embodiments mentioned above provide a further detailed explanation of the purpose, technical solution, and beneficial effects of the present disclosure. It should be understood that the above are only specific embodiments of the present disclosure and are not intended to limit it. Within the spirit and principles of the present disclosure, any modifications, equivalent replacements, improvements, etc. made should be included in the scope of protection of the present disclosure.

1. An image sensing computing unit, which comprises:
a first photosensitive unit, and
a second photosensitive unit connected in series with the first photosensitive unit,
wherein, the changing direction of the first threshold voltage of the first photosensitive unit when receiving light is opposite to the changing direction of the second threshold voltage of the second photosensitive unit when receiving light, so as to realize the in-situ logic operation between the light input signals.

2. The image sensing computing unit of claim 1, wherein the first photosensitive unit comprises:
a first transistor,
a first buried oxide layer located below the first transistor;
a first doped well layer located below the first buried oxide layer.

3. The image sensing computing unit of claim 2, wherein the second photosensitive unit comprises:
a second transistor,
a second buried oxide layer located below the second transistor;
a second doped well layer located below the second buried oxide layer.

4. The image sensing computing unit of claim 3, wherein the transistor type of the first transistor is different from the transistor type of the second transistor, and the well doped type of the first doped well layer is the same as the well doped type of the second doped well layer.

5. The image sensing computing unit of claim 3, wherein,
the source electrode of the first transistor is connected to the power supply voltage,
the drain electrode of the first transistor is connected to the drain electrode of the second transistor, and
the source electrode of the second transistor is grounded;
wherein the gate electrode of the first transistor is connected to a first gate control voltage, the gate electrode of the second transistor is connected to a second gate control voltage, the first doped well layer is connected to a first well control voltage, and the second doped well layer is connected to a second well control voltage.

6. An operating method of the image sensing computing unit according to claim 1, which comprises:
performing an exposure operation on the image sensing computing unit in the off state, so that the equivalent resistance of the first photosensitive unit and/or the second photosensitive unit in the image sensing computing unit changes;
controlling the first gate control voltage of the first photosensitive unit and/or the second gate control voltage of the second photosensitive unit after the exposure operation, which is to generate the output voltage of the image sensing computing unit and achieve the readout operation for the image sensing arithmetic unit; and
controlling the first gate control voltage of the first photosensitive unit and/or the second gate control voltage of the second photosensitive unit that has undergone the readout operation, which is to turn off the first photosensitive unit and/or the second photosensitive unit; and simultaneously controlling the first well control voltage and/or the second well control voltage to implement a reset operation for the image sensing computing unit.

7. The operating method of claim 6, wherein the performing an exposure operation on the image sensing computing unit in an off state comprises:
controlling the first gate control voltage of the first photosensitive unit in the image sensing computing unit and/or the second gate control voltage of the second photosensitive unit in the image sensing computing unit, so that the first photosensitive unit and/or the second photosensitive unit in the image sensing computing unit are turned off, which makes that the image sensing computing unit is in the off state; and
controlling the first well control voltage of the first photosensitive unit and/or the second well control voltage of the second photosensitive unit to implement the exposure operation.

8. The operating method of claim 6, wherein controlling the first gate control voltage of the first photosensitive unit and/or the second gate control voltage of the second photosensitive unit in the image sensing computing unit after the exposure operation to generate an output voltage of the image sensing computing unit, comprising:
when the first well control voltage of the first photosensitive unit and/or the second well control voltage of the second photosensitive unit remain unchanged, controlling the first gate control voltage and/or the second gate control voltage to turn on the first photosensitive unit and/or the second photosensitive unit; and
reading the drain terminal voltage between the first photosensitive unit and the second photosensitive unit as the output voltage.

9. An image sensing computer, comprising an image sensing array comprising a plurality of image sensing computing units of claim 1.

10. An electronic device comprising the image sensing computer of claim 9.
